(19) United States
(12) Patent Application Publication
(10) Pub. No.: US 2017/0171965 A1
(43) Pub. Date: Jun. 15, 2017

(54) STRETCHABLE ELECTRONIC DEVICE AND METHOD OF FABRICATING THE SAME

(71) Applicant: ELECTRONICS AND TELECOMMUNICATIONS RESEARCH INSTITUTE, Daejeon (KR)

(72) Inventors: Doo Hyeb YOUN, Sejong-si (KR); Woong Shik YOU, Sejong-si (KR); Jin Tae OH, Daejeon (KR)

(73) Assignee: ELECTRONICS AND TELECOMMUNICATIONS RESEARCH INSTITUTE, Daejeon (KR)

(21) Appl. No.: 15/221,209

(22) Filed: Jul. 27, 2016

(30) Foreign Application Priority Data
Dec. 10, 2015 (KR) 10-2015-0176187

(51) Int. Cl. H05K 1/02

(52) U.S. Cl. CPC H05K 1/0283

(57) ABSTRACT

A stretchable electronic device includes a flexible substrate, a conductive fiber pattern formed on the flexible substrate, the conductive fiber pattern having a repetitive circular structure, and a graphene material attached to the conductive fiber pattern.

### CROSS-REFERENCE TO RELATED APPLICATION

The present application claims priority to Korean patent application number 10-2015-0176187 filed on Dec. 10, 2015, the entire disclosure of which is incorporated herein in its entirety by reference.

### BACKGROUND

1. Field

An aspect of the present disclosure relates to an electronic device and a method of fabricating the same, and more particularly, to a stretchable electronic device using a conductive fiber pattern and a method of fabricating the same.

2. Description of the Related Art

Fiber-based electronic devices can be freely pulled or bent. Particularly, fibers have various advantages such as elongation, weaving feasibility, wide surface areas, various surface processing and easy composition of composite materials, and thus it will be highly likely that the fabrics will be applied to electronic devices. However, technologies related to this still stay at conceptual levels.

A majority of fibers are composed of polymer materials, and most of the polymer materials are materials having low electrical conductivities. Therefore, the fibers are typically used as electric insulators, and it is inappropriate that the fibers are used as conductive materials.

Conventionally, in order to overcome such a problem, a metallic material having an electrically conductive property was added to a polymer material constituting a fiber, thereby fabricating a fiber pattern having an electrical conductivity.

However, a conductive fiber or fabric fabricated in such a manner has excellent conductivity, and, on the other hands, the mechanical stretchability of the conductive fiber or fabric is weak. Therefore, it is difficult for the fiber or fabric to be directly used in electronic devices or to be used as a connection member for connecting electronic devices to each other.

### SUMMARY

Embodiments provide a stretchable electronic device using a conductive fiber pattern having excellent conductivity and stretchability, and a method of fabricating the stretchable electronic device.

According to an aspect of the present disclosure, there is provided a stretchable electronic device including: a flexible substrate; a conductive fiber pattern formed on the flexible substrate, the conductive fiber pattern having a repetitive circular structure; and a graphene material attached to the conductive fiber pattern.

According to an aspect of the present disclosure, there is provided a method of fabricating a stretchable electronic device, the method including: preparing a mixed solution in which a polymer material and a metallic material are dispersed; electrically spinning the mixed solution, thereby forming a conductive fiber pattern having a repetitive circular structure; annealing the conductive fiber pattern; and dipping the conductive fiber pattern into a graphene dispersion solution, thereby attaching a graphene material to a surface of the conductive fiber pattern.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIGS. 1A and 1B are views illustrating a structure of a stretchable electronic device according to an embodiment of the present disclosure.

FIGS. 2A to 2C are views illustrating a structure of a stretchable electronic device according to an embodiment of the present disclosure.

FIG. 3 is a schematic view illustrating a method of forming a fiber pattern using electro-spinning (ES) according to an embodiment of the present disclosure.

FIGS. 4A and 4B are schematic views illustrating a method of forming a fiber pattern using near-field electro-spinning (NFES) according to an embodiment of the present disclosure.

FIGS. 5A to 5E are views illustrating a process of fabricating a flexible electronic device according to an embodiment of the present disclosure.

FIG. 6 is an electron microscope photograph of a hybrid structure of silver wires and graphene particles, which is actually fabricated using a method of fabricating a stretchable electronic device according to an embodiment of the present disclosure.

FIG. 7 is an actual photograph of a fiber pattern fabricated on an aluminum substrate.

### DETAILED DESCRIPTION

Hereinafter, exemplary embodiments of the present disclosure will be described. In the drawings, the thicknesses and the intervals of elements are exaggerated for convenience of illustration, and may be exaggerated compared to an actual physical thickness. In describing the present disclosure, a publicly known configuration irrelevant to the principal point of the present disclosure may be omitted. It should note that in giving reference numerals to elements of each drawing, like reference numerals refer to like elements even though like elements are shown in different drawings.

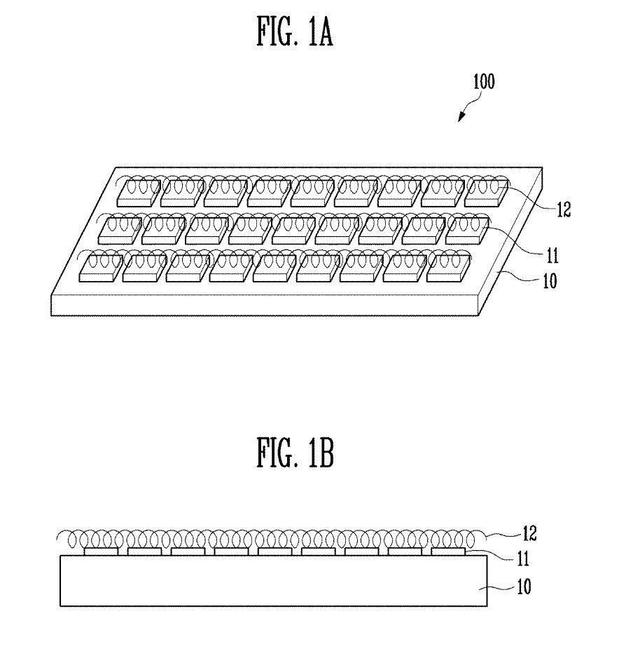

FIGS. 1A and 1B are views illustrating a structure of a stretchable electronic device according to an embodiment of the present disclosure.

Referring to FIGS. 1A and 1B, the stretchable electronic device 100 according to the embodiment of the present disclosure includes a substrate 10, an electrode pattern 11 formed on the substrate 10, and a conductive fiber pattern 12 formed on the electrode pattern 11.

The substrate 10 may be a flexible substrate such as a rubber substrate. The electrode pattern 11 is formed of a conductive layer such as a metal, and may include a plurality of electrode layers spaced apart from each other at a predetermined distance. For example, the electrode pattern 11 may be a sensing electrode of a sensor. The conductive fiber pattern 12 is electrically connected to the electrode pattern 11, and may have a tangled structure. Here, the tangled structure may be a structure in which an amorphous overlapping structure such as a net, a web, or a skein is repeated, or may be a structure in which a circular overlapping structure such as a spring structure or a spiral structure is repeated.

According to the structure described above, the plurality of electrode layers included in the electrode pattern 11 are electrically connected to each other by the conductive fiber pattern 12. Even when the distance between the plurality of electrode layers is increased as the substrate 10 is stretched or when the substrate 10 is warped as the substrate is stretched, the conductive fiber pattern 12 can be stretched in a state in which the plurality of electrode layers are electrically connected to each other by the conductive fiber pattern 12 because of its structural characteristic. That is, if the substrate 10 is stretched, the overlapping structure of the conductive fiber pattern 12 is unfolded, and the connection state of the conductive fiber pattern 12 is maintained as it is. Thus, the electrical connection of the plurality of electrode layers can also be maintained.

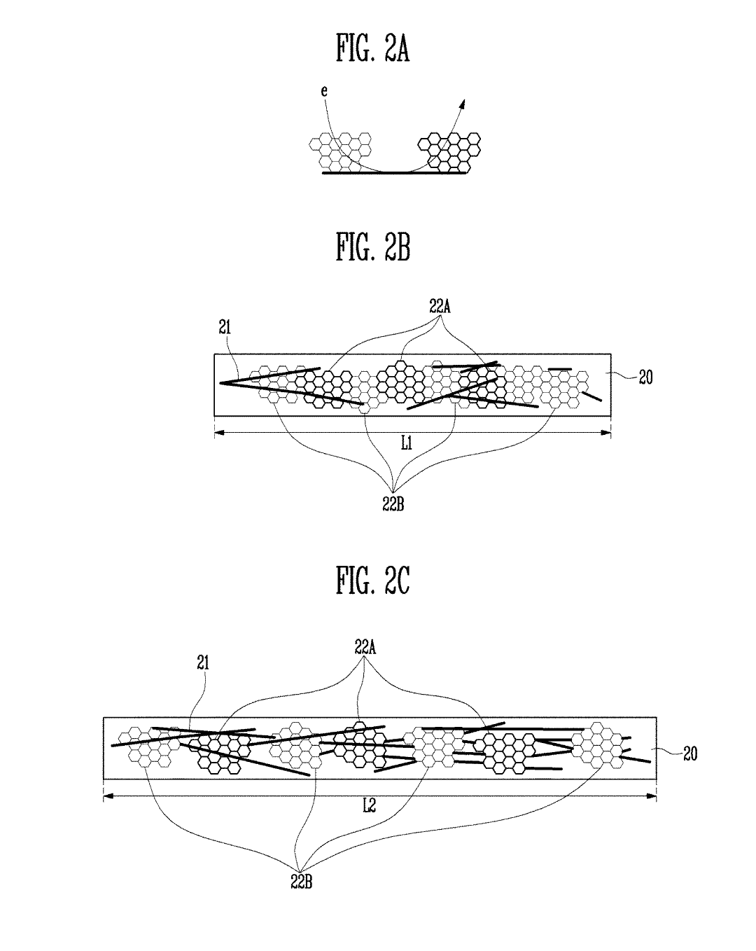

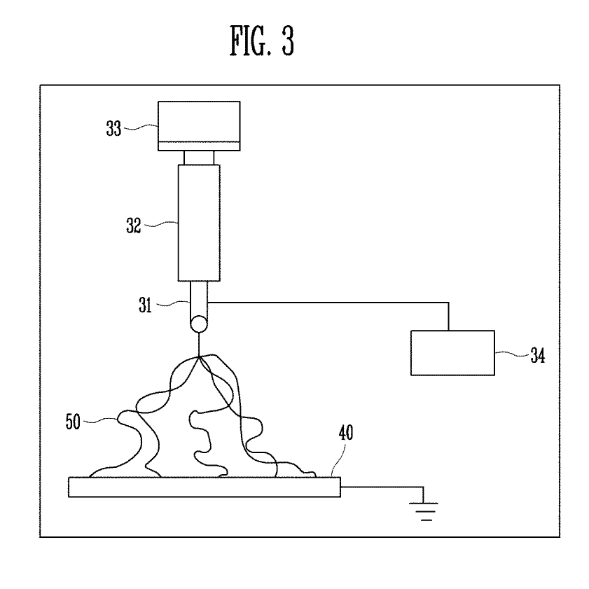

FIGS. 2A to 2C are views illustrating a structure of a stretchable electronic device according to an embodiment of the present disclosure, which shows a conductive fiber pattern having a hybrid structure, to which a graphene material is attached.

Referring to FIG. 2A, the conductive fiber pattern may have a structure of a nanowire 21. First graphene materials 22A and second graphene materials 22B are attached to the nanowire 21. The first graphene materials 22A and the second graphene materials 22B may be located to be spaced apart from each other. Here, the nanowire 21 is formed of a material capable of conducting electric charges therethrough, and has conductivity. Thus, although the first graphene materials 22A and the second graphene materials 22B are located to be spaced apart from each other, the first graphene materials 22A and the second graphene materials 22B can be electrically connected to each other by the nanowire 21. That is, if current flows through the first graphene materials 22A, the current flows in the second graphene materials 22B through the nanowire 21 without interruption of an electrical signal. For example, the nanowire 21 may be a silver (Ag) wire, and the first and second graphene materials 22A and 22B may be graphene flakes.

Referring to FIG. 2B, the nanowire 21 and the plurality of graphene materials 22A and 22B are formed on the substrate 20 having a first length L1. For example, a solution prepared by mixing a silver wire and graphene flakes is printed on the substrate 20 using electric spinning, thereby forming an electrode structure having a line shape. Here, the nanowire 21 has a tangled structure in which a plurality of segments are arranged to overlap with each other, and the plurality of graphene materials 22A and 22B may also be arranged to overlap with each other.

Referring to FIG. 2C, as the substrate 20 is stretched to a second length L2, the first graphene materials 22A and the second graphene materials 22B are spaced apart from each other. At this time, the positions of a plurality of nanosegments are also changed along the stretched substrate 20, but the overlapping structure is still maintained. That is, as the substrate 20 is stretched, the number of overlapping regions is decreased, but the overlapping structure is still maintained. Thus, the first graphene materials 22A and the second graphene materials 22B, which are spaced apart from each other, can be electrically connected to each other.

By applying the above-described structure, it is possible to implement a hybrid structure in which its lower portion is filled with the nanowire 21 and a conductive polymer, and a graphene material for biochemical material detection is attached to its upper portion. Here, the nanowire 21 at the lower portion of the hybrid structure may be a sensing electrode, and a biochemical detection device (sensor) may be fabricated using the sensing electrode. Thus, it is possible to fabricate stretchable detection device of which electrical characteristics are not changed even though it is warped or stretched.

For reference, in these figures, the mixed graphene flakes are called as the first graphene materials 22A and the second graphene materials 22B for convenience of description so as to distinguish the graphene flakes from each other, but the present disclosure is not limited thereto. In addition, the silver wire may have the above-described circular overlapping structure.

FIG. 3 is a schematic view illustrating a method of forming a fiber pattern using electro-spinning (ES) according to an embodiment of the present disclosure.

An ES process is a technique of spinning a polymer solution or polymer melt using an electrostatic force, thereby forming a fine pattern having a line width of a few tens to a few hundreds of nanometers. In the ES process, the fine pattern is spun using an electrostatic force generated by a high voltage of a few kV or more. Hereinafter, a method of fabricating a fiber pattern using ES with reference to FIG. 3.

Referring to FIG. 3, an ES apparatus includes a nozzle 31, a syringe 32, a syringe pump 33, and a power supply 34. First, a solution prepared by mixing a polymer material having a predetermined viscosity, e.g., a viscosity value of 3 to 90 cps and a conductive metal structure is stored inside the syringe 32. Subsequently, a constant pressure is applied to the inside of the syringe 32 through the syringe pump 33, thereby pushing the solution through the nozzle 31. Accordingly, a droplet is formed at the end of the nozzle 31, and the shape of the droplet is maintained by surface tension. Subsequently, a voltage is applied to the nozzle 31 through the high-voltage power supply 34, and a substrate 40 is grounded. If an electric field applied from an outside has a specific threshold value, e.g., a value greater than the surface tension by which the shape of the droplet is to be maintained as it is, a fine conductive fiber pattern 50 from the nozzle 31 is formed and drops in the shape of an inverted triangle onto a surface of the substrate 40. At this time, the conductive fiber pattern 50 injected from the end of the nozzle 31 is attached to the substrate 40 while being injected by electrostatic repulsion against the voltage applied to the nozzle 31. Here, the nozzle 31 may be made of a metallic material, and the syringe 32 pushes the solution at a speed of 0.01 to 0.1 Ml/h per hole from the nozzle 31. Accordingly, there can be formed a fiber pattern in an irregular form, as if a skein was tangled.

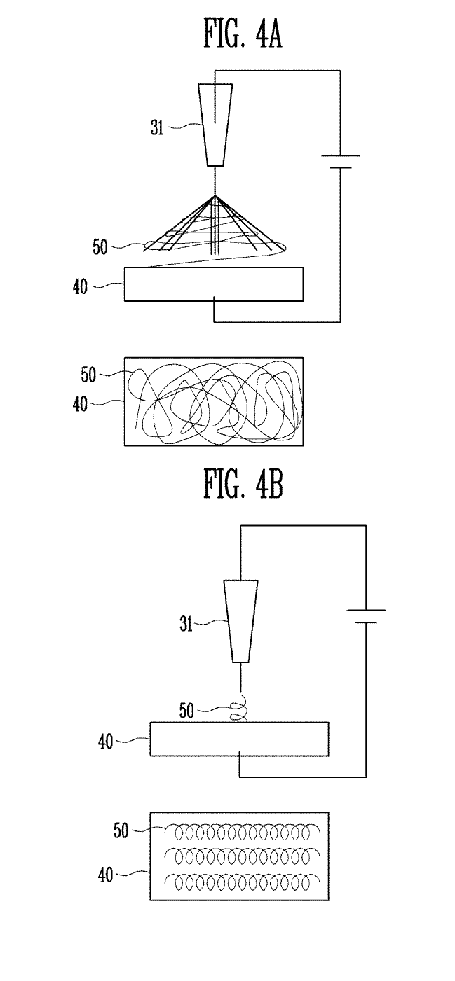

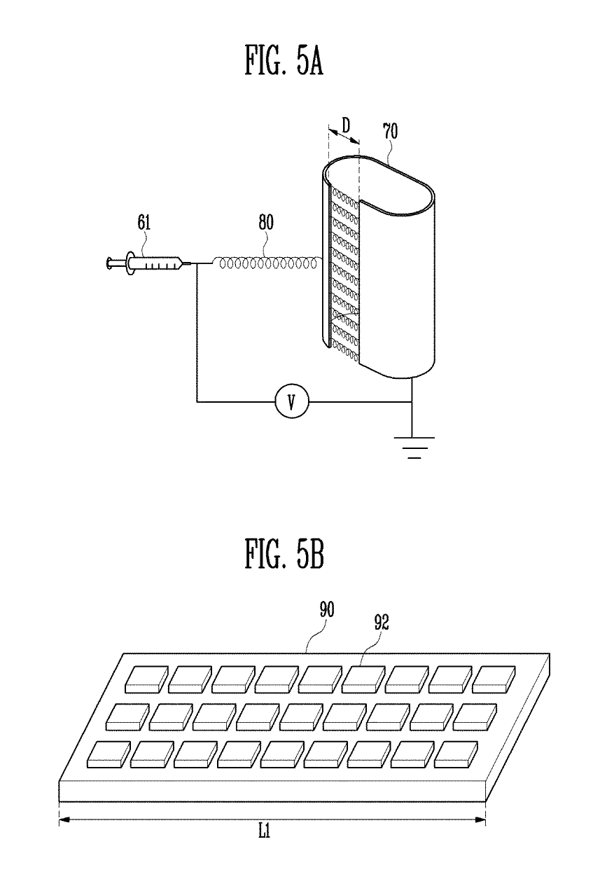

FIGS. 4A and 4B are schematic views illustrating a method of forming a fiber pattern having a free-standing structure using near-field electro-spinning (NFES) according to an embodiment of the present disclosure. Hereinafter, a method of controlling the form of the fiber pattern depending on a distance between the nozzle 31 and the substrate 40 will be described with reference to FIGS. 4A and 4B.

First, a polymer material and a conductive metallic material are mixed together, thereby preparing a mixed solution. Here, the polymer material may be any one selected from the group consisting of polyvinyl alcohol (PVA), polyurethane (PU), polyimide (PI), polyethylene oxide (PEO), polyvinylpyrrolidone (PVP), polystyrene (PS), and polyacrylonitrile (PAN). The metallic material may have the form of a metal wire or metal flake. Also, the metallic material may be any one selected from the group consisting of silver (Ag), copper (Cu), gold (Au), platinum (Pt), molybdenum (Mo), tungsten (W), nickel (Ni), and chromium (Cr).

Subsequently, the mixed solution stored in the syringe is extruded in the form of a droplet from the nozzle 31. If a voltage applied in the vertical direction between the nozzle 31 and the substrate 40 becomes greater than the surface tension of the droplet, a conductive fiber pattern 50 is spun. At this time, the fiber pattern 50 is spun in a linear jet flow. If the force by which the droplet is to spread in the horizontal direction is equilibrated with the voltage applied in the vertical direction, the conductive fiber pattern 50 having a repetitive circular structure such as a vortex shape, a spiral shape, or a spring shape is spun. Subsequently, the conductive fiber pattern 50 is annealed. Accordingly, a polymer component included in the conductive fiber pattern 50 can be removed.

Here, the radius of curvature of the conductive fiber pattern 50 injected in a circular shape may be adjusted depending on a distance between the nozzle 31 and the substrate 40. When the distance between the nozzle 31 and the substrate 40 is relatively distant as shown in FIG. 4A, the radius of curvature of the fiber pattern is increased, and hence the fiber pattern may be irregularly spun on the entire substrate 40. Therefore, it is difficult to control the form of the fiber pattern and the position at which the fiber pattern is formed. When the distance between the nozzle 31 and the substrate 40 is relatively close as shown in FIG. 4B, the radius of curvature of the fiber pattern is decreased, and hence the fiber pattern having a regular form can be formed at a desired position. Particularly, when the distance between the nozzle 31 and the substrate 40 is adjusted to 1 to 5 nm, the conductive fiber pattern 50 injected in a circular shape from the nozzle 31 while having a relatively small radius of curvature can be formed using the linear jet flow.

As described above, the distance between the nozzle 31 and the substrate 40 is adjusted to 5 nm or less, a fiber pattern having a repetitive circular structure can be fabricated at a specific position. Further, if the above-described method is applied to the fabrication of an electronic device, an electrode pattern is previously formed on the substrate 40, and a spring-shaped fiber pattern is formed on only the electrode pattern, so that the electronic device can be driven by allowing current to be selectively introduced into only an electrode portion at which the fiber pattern is formed.

In addition, the magnitude of the applied voltage, the viscosity of the solution, the moving speeds of the nozzle 31 in X, Y, and Z directions, the size of a hole of the nozzle 31, through which the solution is discharged, and the like may be adjusted, thereby controlling the form and line width of the conductive fiber pattern 50. Particularly, the line width of the conductive fiber pattern 50 may be controlled to be within a few to a few tens of μm. For example, when the polymer solution has a viscosity of 10 to 50 cps, a fiber pattern having the form of a third-dimensional mat is formed on the surface of the substrate 40 as shown in FIG. 4A. Such a mat pattern is not broken and has a continuous form.

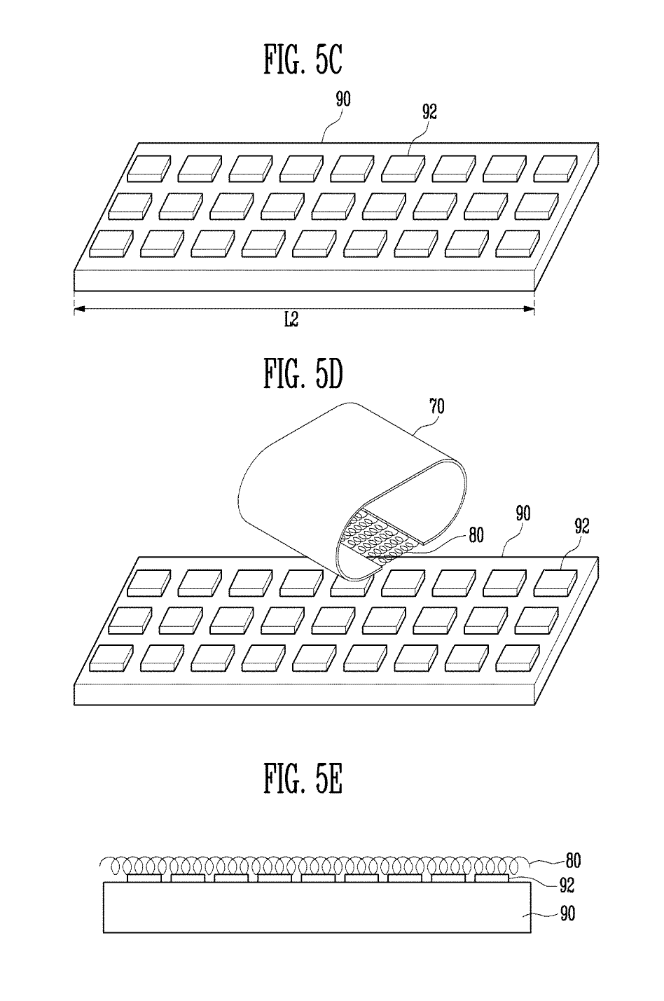

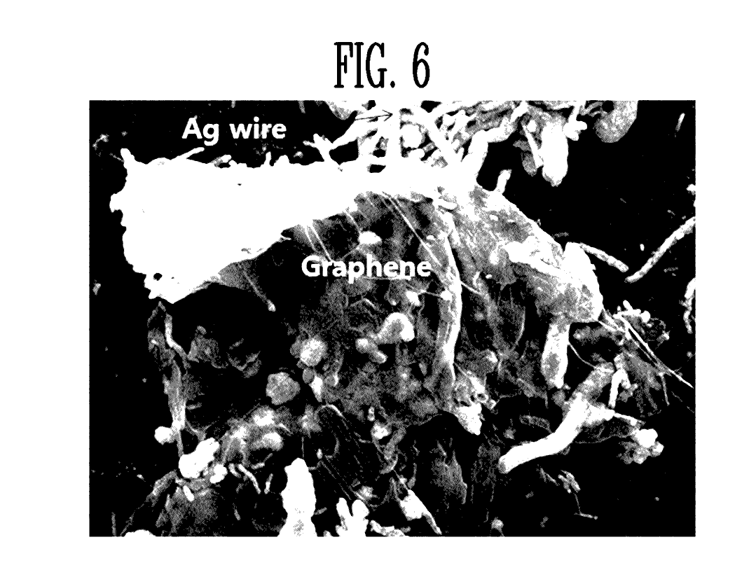

FIGS. 5A to 5E are views illustrating a process of fabricating a flexible electronic device according to an embodiment of the present disclosure. Hereinafter, a method of fabricating a flexible electronic device having a hybrid structure of a silver wire and a graphene sheet will be described with reference to FIGS. 5A to 5E.

Referring to FIG. 5A, a conductive fiber pattern 80 having a repetitive circular structure is formed on an arbitrary substrate 70. For example, there is prepared a mixed solution in which a polymer solution and silver wires are uniformly dispersed. Subsequently, the mixed solution is stored in a syringe, and the conductive fiber pattern 80 is then spun from a nozzle using a syringe pump. At this time, the distance between the nozzle and the arbitrary substrate 70 is adjusted to 5 nm or less, thereby forming the conductive fiber pattern 80 having the repetitive circular structure. Here, the arbitrary substrate 70 may be an aluminum foil, and the conductive fiber pattern 80 may be formed in a state in which the aluminum foil is folded at a distance D of 50 to 100 nm.

Referring to FIG. 5B, an electrode pattern 92 is formed on a flexible substrate 90. Here, the electrode pattern 92 may include a plurality of electrodes spaced apart from each other at a predetermined distance. The flexible substrate 90 may be a rubber substrate having a first length L1.

Referring to FIGS. 5C and 5D, the flexible substrate 90 is stretched to a second length L2, and the conductive fiber pattern 80 formed on the arbitrary substrate 70 is then transferred onto the flexible substrate 90.

Referring to FIG. 5E, the conductive fiber pattern 80 is attached on the electrode pattern 92 of the flexible substrate 90. At this time, if the stretched flexible substrate 90 is returned to have the first length L1, the period of the repetitive structure of the conductive fiber pattern 80 is shortened.

For reference, although not shown in these figures, the conductive fiber pattern 80 may be annealed. In addition, the conductive fiber pattern 80 is dipped into a graphene dispersion solution, thereby attaching a graphene material to the conductive fiber pattern 80. For example, after the conductive fiber pattern 80 formed using the ES is annealed, the conductive fiber pattern 80 is transferred onto the flexible substrate 90, and a graphene material may be attached to the conductive fiber pattern 80 transferred onto the flexible substrate 90.

According to the above-described method, it is possible to fabricate an inter-connection electrode structure that can be freely bent or stretched, and a stretchable electronic device can be fabricated using the inter-connection electrode structure. Particularly, since the graphene material has a detection characteristic with respect to a biochemical material, the conductive fiber pattern 80 and the graphene material are formed on a flexible substrate having a sensing electrode pattern formed thereon, so that it is possible to fabricate a stretchable biochemical sensor having a hybrid structure with a conductive metal-fiber.

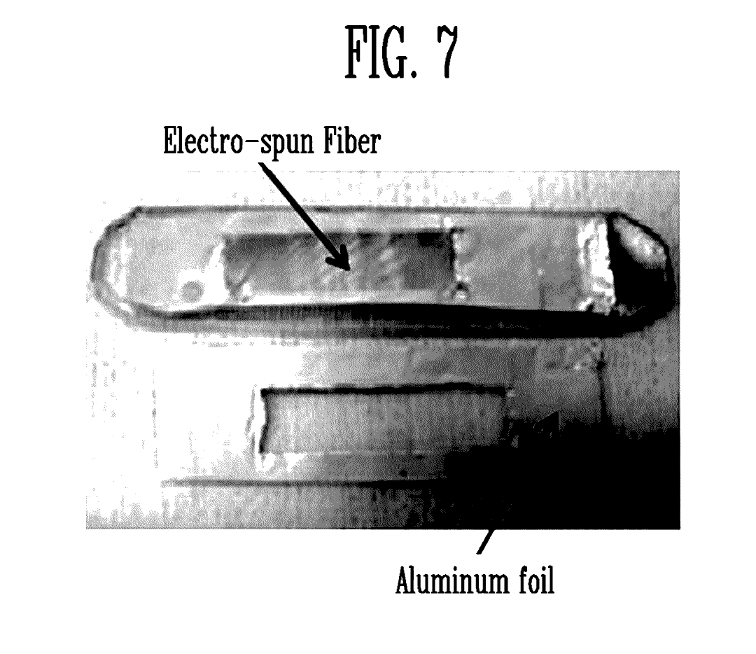

FIG. 6 is an electron microscope photograph of a hybrid structure of silver wires and graphene particles, which is actually fabricated using a method of fabricating a stretchable electronic device according to an embodiment of the present disclosure.

Referring to FIG. 6, silver wires are located at a lower portion of the hybrid structure, and a graphene sheet having a thin paper form is located at an upper portion of the hybrid structure. Thus, it can be seen that the graphene sheet at the upper portion is electrically connected to the silver wire at the lower portion while entirely covering the surface of the silver wire at the lower portion.

FIG. 7 is an actual photograph of a fiber pattern fabricated on an aluminum substrate.

Referring to FIG. 7, a conductive fiber pattern electrically spun on an aluminum foil can be seen.

According to the present disclosure, a conductive fiber pattern having a spring structure can be formed using the NFES. The conductive fiber pattern having the spring structure can be freely bent or stretched. Although the shape of the conductive fiber pattern is changed, a conductive fiber is not broken, and can maintain its unique characteristic. Accordingly, a stretchable electronic device can be fabricated using the conductive fiber pattern. For example, it is possible to fabricate an inter-connection electrode structure or an attachable flexible electronic device attached to a surface having a certain curvature, such as a helmet or a wrist. In addition, it is possible to fabricate an attachable flexible electronic device attached to an area in which the distance between two electrodes is varied, such as when an arm is folded or unfolded.

Further, a conductive fiber pattern is dipped into a solution in which graphene is uniformly dispersed, so that a graphene material can be uniformly attached on the surface of the conductive fiber pattern. Accordingly, the graphene material having a detection characteristic with respect to a biochemical material is attached to the conductive fiber pattern, so that it is possible to fabricate a hybrid structure of a conductive fiber and graphene. Also, it is possible to fabricate an electronic device such as a biochemical sensor using the hybrid structure

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A stretchable electronic device comprising:
a flexible substrate;
a conductive fiber pattern formed on the flexible substrate, the conductive fiber pattern having a repetitive circular structure; and
a graphene material attached to the conductive fiber pattern.

2. The stretchable electronic device of claim 1, further comprising an electrode pattern formed on the flexible substrate, the electrode pattern being electrically connected to the conductive fiber pattern.

3. The stretchable electronic device of claim 1, wherein the stretchable electronic device is a biochemical sensor.

4. The stretchable electronic device of claim 1, wherein the conductive fiber pattern includes a polymer material and a metallic material.

5. The stretchable electronic device of claim 4, wherein the metallic material is any one selected from the group consisting of silver (Ag), copper (Cu), gold (Au), platinum (Pt), molybdenum (Mo), tungsten (W), nickel (Ni), and chromium (Cr).

6. The stretchable electronic device of claim 4, wherein the polymer material is any one selected from the group consisting of polyvinyl alcohol (PVA), polyurethane (PU), polyimide (PI), polyethylene oxide (PEO), polyvinylpyrrolidone (PVP), polystyrene (PS), and polyacrylonitrile (PAN).

7. A method of fabricating a stretchable electronic device, the method comprising:
preparing a mixed solution in which a polymer material and a metallic material are dispersed;
electrically spinning the mixed solution, thereby forming a conductive fiber pattern having a repetitive circular structure;
annealing the conductive fiber pattern; and
dipping the conductive fiber pattern into a graphene dispersion solution, thereby attaching a graphene material to a surface of the conductive fiber pattern.

8. The method of claim 7, wherein, in the forming of the conductive fiber pattern, the distance between a nozzle of an electro-spinning apparatus and a substrate is adjusted to 1 to 5 mm.

9. The method of claim 7, further comprising transferring the conductive fiber pattern onto a flexible substrate.

10. The method of claim 9, wherein the conductive fiber pattern is transferred in a state in which the flexible substrate is stretched.
